(19) United States
(12) Patent Application Publication
(10) Pub. No.: US 2025/0141179 A1
(43) Pub. Date: May 1, 2025

(54) LASER COMPONENT

(71) Applicant: ams-OSRAM International GmbH, Regensburg (DE)

(72) Inventors: Elmar BAUR, Regensburg (DE); Jan SEIDENFADEN, Neumarkt I.D. Oberpfalz (DE); Thomas KIPPES, Neumarkt (DE)

(73) Assignee: ams-OSRAM International GmbH, Regensburg (DE)

(21) Appl. No.: 18/837,239

(22) PCT Filed: Dec. 7, 2022
(86) PCT No.: PCT/EP2022/084830

§ 371 Date: Aug. 9, 2024

(30) Foreign Application Priority Data
Feb. 11, 2022 (DE) 102022103260.4

(51) Int. Cl. H01S 5/0235; H01S 5/0225; H01S 5/028

(52) U.S. Cl. CPC H01S 5/0235; H01S 5/0225; H01S 5/028

(57) ABSTRACT

The invention relates to a laser component including a semiconductor laser chip having a laser facet with an active zone, and an optical element which is mounted after the semiconductor laser chip on the laser facet, wherein the semiconductor laser chip and the optical element are connected to each other by a welding connection that is free from welding additives.

### CROSS-REFERENCE TO RELATED APPLICATIONS

The present application is a national stage entry from International Application No. PCT/EP2022/084830, filed on Dec. 7, 2022, published as International Publication No. WO 2023/151848 A1 on Aug. 17, 2023, and claims priority to German Patent Application No. 10 2022 103 260.4, filed Feb. 11, 2022, the disclosures of all of which are hereby incorporated by reference in their entireties.

### FIELD

A laser component is disclosed. In addition, a method of manufacturing a laser component is disclosed.

### BACKGROUND

One of the tasks to be solved is to specify a laser component that is particularly cost-effective. A further task to be solved may be, among other things, to specify a laser component which is particularly resistant to ageing. A further task to be solved is, among other things, to specify a method of manufacturing such a laser component.

A laser component is specified. During operation, the laser component generates electromagnetic radiation, in particular laser radiation. The laser component is set up to generate electromagnetic radiation with a wavelength that lies in the wavelength range between infrared radiation and UV radiation.

### SUMMARY

According to at least one embodiment of the laser component, the laser component comprises a semiconductor laser chip. The semiconductor laser chip may, for example, be an edge-emitting semiconductor laser chip or a surface-emitting semiconductor laser chip.

The semiconductor laser chip comprises, for example, a semiconductor body, reflective outer surfaces that form a resonator and electrical connection points for contacting the semiconductor laser chip.

The semiconductor laser chip comprises a laser facet. The laser radiation generated by the semiconductor laser chip is emitted from the laser facet of the semiconductor laser chip during operation. The laser facet is formed, for example, by an outer surface of the semiconductor laser chip, such as a side surface or a cover surface.

The laser facet comprises an active zone, which comprises the region of the laser facet at which the electromagnetic radiation generated during operation leaves the semiconductor laser. For example, in the region of the active zone, an active layer of the semiconductor laser chip is adjacent to a reflective layer of the semiconductor laser chip, which is part of the resonator of the semiconductor laser chip.

According to at least one embodiment of the laser component, the laser component comprises an optical element that is arranged downstream of the semiconductor laser chip at the laser facet. The optical element follows the laser facet of the semiconductor laser chip, in particular in a radiation direction of the semiconductor laser chip.

This makes it possible for all or at least a large part of the laser radiation leaving the semiconductor laser chip to pass through the optical element and be optically influenced by it.

The optical element is, for example, an optical element for beam shaping by means of optical refraction. For example, the optical element is then a lens for focusing the laser beam. Alternatively or additionally, it is possible that the optical element is a diffractive optical element (also DOE), in which the beam shaping is based on the principle of optical diffraction.

The optical element is formed with a material that is transparent to the laser radiation, such as a glass, a semiconductor material and/or a plastic material.

No other component of the laser component is arranged between the optical element and the laser facet. However, there may be a gap between the laser facet and the optical element, at least sectionally, which is filled with air, for example.

According to at least one embodiment of the laser component, the semiconductor laser chip and the optical element are joined together by means of a welded joint. A welded joint is understood here and in the following to mean a non-destructively detachable mechanical connection that is generated between two joining partners of the laser component under the action of heat and/or pressure.

In particular, the welded joint is free of welding consumables. This means that the welded joint is only formed by the material of the joining partners, which are joined together by the welded joint. The joining partners are therefore directly connected to each other without any other joining material such as welding consumables or an adhesive.

According to at least one embodiment of the laser component, the laser component comprises a semiconductor laser chip with a laser facet comprising an active zone and an optical element arranged downstream of the semiconductor laser chip at the laser facet. The semiconductor laser chip and the optical element are connected to each other by means of a welded joint that is free of welding consumables.

The laser component is based on the following considerations, among others. In semiconductor laser components that are operated in an open atmosphere, for example, a deposit of foreign substances is observed on the laser facet, which leads to a degradation of the laser component, for example due to a decrease in light power. The deposit can be caused by dust or suspended particles in the surrounding air.

The laser component described here is based on the idea that an arrangement of the optical element particularly close to the laser facet reduces, inhibits and/or prevents the deposition of foreign substances from the surrounding atmosphere. The use of a welded joint makes it possible to dispense with joining materials, which enables the laser component to be manufactured particularly cost-effectively. In addition, no further materials, for example joining materials, need to be optimized with regard to their optical and/or thermal properties, which in turn enables particularly simple and cost-effective production.

According to at least one embodiment of the laser component, the distance between the optical element and the laser facet is at most 10 μm, in particular at most 7 μm or at most 1 μm. Distances of 500 nm and less are also possible. In particular, the smallest distance between the optical element and the laser facet is in the area of the active zone. It has been shown that such small distances ensure that the deposition of foreign substances from the atmosphere on the laser facet is greatly reduced or prevented.

According to at least one embodiment of the laser component, the optical element and the semiconductor laser chip are in direct contact with each other at the laser facet. The direct contact between the two elements can, for example, be mediated by the welded joint. That is, in this case, the welded joint may be located between the optical element and the semiconductor laser chip, so that direct physical contact between these two components of the laser component is mediated by the welded joint.

According to at least one embodiment of the laser component, the laser component comprises a carrier. The other components of the laser component, in particular the semiconductor laser chip and the optical element, are attached to the carrier. The carrier then represents the mechanically supporting component of the laser component. The optical element is connected to the semiconductor laser chip by means of the carrier and the welded joint is arranged between the optical element and the carrier.

A welded joint can then also be arranged between the optical element and the semiconductor laser chip, or these two components are not connected to each other by a direct welded joint. In other words, it is in particular also possible for the optical element and the semiconductor laser chip to be connected to each other via the carrier as an intermediary and for the welded joint to be arranged only between the optical element and the carrier.

On its outer surface facing the optical element, the carrier can, for example, have a material that is suitable for the welded joint. For example, the outer surface of the carrier facing the optical element may comprise a layer formed with a metal oxide and/or a semiconductor oxide, such as silicon dioxide, a glass and/or a glass ceramic.

According to at least one embodiment of the laser component, the welded joint comprises a welding seam that extends in a connection area between the optical element and the carrier and comprises material of the optical element and the carrier.

According to at least one embodiment of the laser component, the welded joint is arranged between the optical element and the semiconductor laser chip. It is additionally possible that a welded joint is also arranged between the optical element and a carrier of the laser component. However, it is also possible that the welded joint between the optical element and the semiconductor laser chip is the only connection between these two components of the laser component. The welded joint provides direct physical contact between the optical element and the semiconductor laser chip.

The semiconductor laser chip can, for example, comprise a reflective layer on the laser facet, which comprises metal oxides and/or semiconductor oxides. The reflective layer then forms part of the resonator of the semiconductor laser chip. In particular, the welded joint can be formed with material from the optical element and the reflective layer.

For example, the reflective layer may comprise silicon dioxide and the optical element may be formed with or consist of glass, so that the welded joint comprises or consists of silicon dioxide, for example.

According to at least one embodiment of the laser component, the welded joint comprises a welding seam. A welding seam connects components in a material-locking manner at a weld joint. A weld joint is understood to be the area in which the components are joined together. In particular, a welding seam is a welded joint along a connecting line or connecting curve. In this case, the components are only joined in a material-locking manner along the connecting line or connecting curve. In other words, a welding seam is spatially limited to an area of the components in which the components are joined together. The welding seam does not connect the components over their entire surface facing each other, in particular not in a planar manner.

According to at least one embodiment of the laser component, the welded joint comprises a welding seam between the optical element and the semiconductor laser chip. In particular, the welding seam between the optical element and the semiconductor laser chip is the only connection between these two components of the laser component. In particular, the connection between the optical element and the semiconductor chip is free of any further joint material. The welding seam provides direct physical contact between the optical element and the semiconductor laser chip.

According to at least one embodiment, the welding seam does not connect the optical element and the semiconductor laser chip in a planar manner. In other words, the welding seam is arranged in a spatially delimiting area between the optical element and the semiconductor laser chip, for example along a line or curve.

According to at least one embodiment of the laser component, the welded joint comprises a welding seam that extends in a connection area between the optical element and the semiconductor laser chip and comprises material of the optical element and the semiconductor laser chip. The welding seam extends along a curve, for example, so that a planar connection between the optical element and the semiconductor laser chip is generated by the welded joint. The welding seam can, for example, comprise several concentric curves and/or meandering curves that are arranged, for example, in a zig-zag pattern between the optical element and the semiconductor laser chip. In this way, it is possible to generate a connection between these two components that is as planar as possible.

It is possible for the welded joint to be spaced from the active zone and only run along one side of the active zone, for example.

According to at least one embodiment of the laser component, the welding seam encloses the active zone laterally. In this case, the welding seam is guided laterally around the active zone in the plane of the connection area between the optical element and the semiconductor laser chip.

In this case, it is possible to hermetically seal the active zone via the welding seam that laterally encloses the active zone, so that the active zone is laterally enclosed by the welding seam, the optical element and the semiconductor laser chip. This ensures that no foreign substances can accumulate in the active zone.

According to at least one embodiment of the laser component, the laser component is free of a hermetically sealed housing. This means, for example, that the laser component can comprise a housing that is not hermetically sealed or the laser component is free of any housing and the components of the laser component are arranged together, for example on a carrier of the laser component.

The absence of a hermetically sealed housing is possible in particular due to the arrangement of the optical element at a short distance from the laser facet and allows the production of particularly compact and cost-effective laser components.

A method of manufacturing a laser component is further disclosed. In particular, a laser component described herein can be manufactured by means of the method. This means that all the features disclosed for the laser component are also disclosed for the method and vice versa.

According to at least one embodiment of the method, a semiconductor laser chip with a laser facet comprising an active zone is first provided.

According to at least one embodiment of the method, an optical element is provided. The optical element is arranged on the laser facet.

According to at least one embodiment of the method, in a further method step, the semiconductor laser chip and the optical element are joined in a connection area by means of a welding process, wherein the welding process is carried out without consumables.

According to at least one embodiment of the method, the method comprises the following steps:
providing a semiconductor laser chip with a laser facet comprising an active zone,
providing an optical element,
arranging the optical element at the laser facet,
joining the semiconductor laser chip and the optical element in a connection area by means of a welding process, wherein the welding process is carried out without welding consumables.

The semiconductor laser chip and the optical element can be connected directly at an interface between the semiconductor laser chip and the optical element by means of the welding process.

Alternatively or additionally, it is possible for the optical element to be joined by means of a welding process in a connection area between the optical element and a carrier, and for the semiconductor laser chip and optical element to be indirectly joined via the carrier after joining to the carrier.

According to at least one embodiment of the method, joining the semiconductor laser chip and the optical element in a connection area by means of a welding process comprises generating a welding seam. In particular, the welding seam between the optical element and the semiconductor laser chip is the only connection between these two components of the laser component. In particular, the connection between the optical element and the semiconductor chip is free of any further joint material.

According to at least one embodiment of the method, the welding seam is not generated in a planar manner between the optical element and the semiconductor laser chip. In particular, the welding seam is generated in a spatially delimiting area between the optical element and the semiconductor laser chip, for example along a line or curve.

According to at least one embodiment of the method, the welding process is carried out by means of a laser beam that is focused in the connection area. For this purpose, a laser beam is guided through the optical element, for example, and focused at the interface between the components to be joined. This creates an area of high power density at the interface in which the joining partners melt locally. The laser beam is then moved along a curve, for example, so that a welding seam is created that is formed with materials from the joining partners.

For example, a welding process such as that offered by Primoceler for joining glass can be used. However, alternative laser welding processes can also be used. When attaching the optical element to a carrier by means of a welded joint, it is also possible to focus the laser through the carrier onto the interface between the laser and the optical element if the carrier material is suitable.

In the following, the laser component described here and the method described here are explained in more detail with reference to embodiment examples and the associated figures.

### BRIEF DESCRIPTION OF THE DRAWINGS

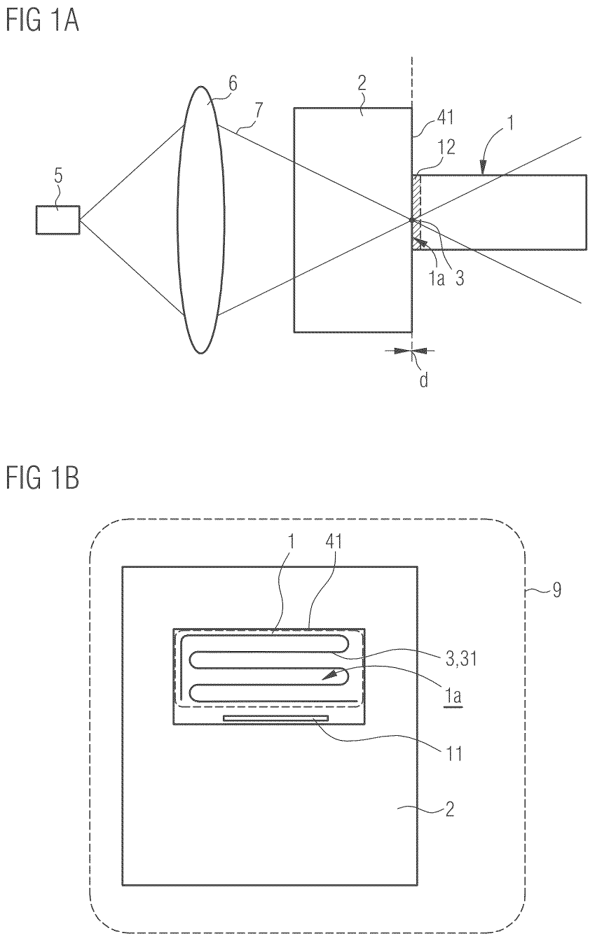

With reference to the schematic representations of FIGS. 1A and 1B, a first exemplary embodiment of a method described herein and a first exemplary embodiment of a laser component described herein are explained in more detail.

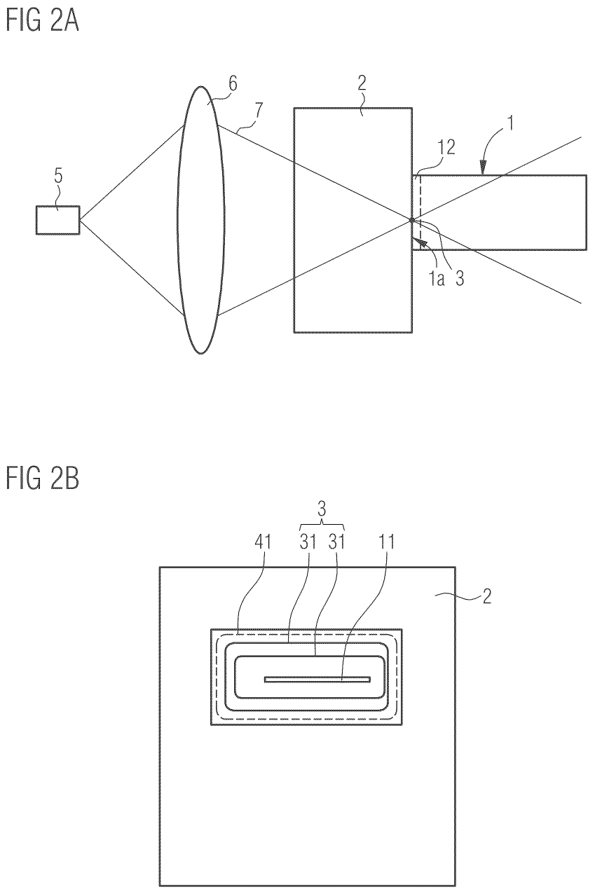

With reference to the schematic representations of FIGS. 2A and 2B, a second exemplary embodiment of a method described herein and a second exemplary embodiment of a laser component described herein are explained in more detail.

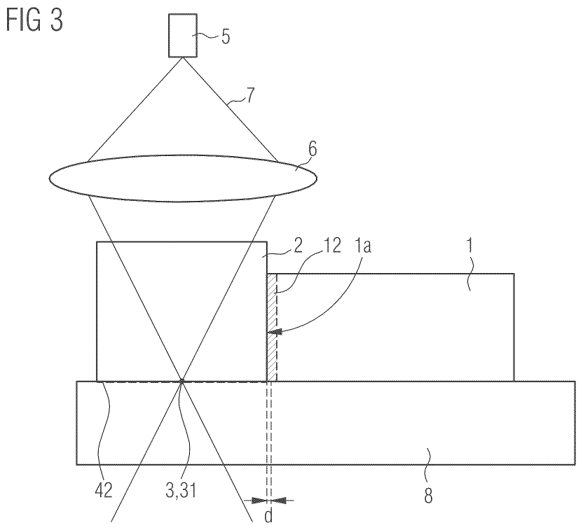

A third exemplary embodiment of a method described herein and a third exemplary embodiment of a laser component described herein are explained in more detail with reference to the schematic representation of FIG. 3.

### DETAILED DESCRIPTION

Elements that are identical, similar or have the same effect are marked with the same reference symbols in the figures. The figures and the proportions of the elements shown in the figures are not to be regarded as being to scale. Rather, individual elements may be shown in exaggerated size for better visualization and/or better comprehensibility.

In connection with the schematic sectional view of FIG. 1A, a first exemplary embodiment of a method described herein is explained in more detail.

In the method, a semiconductor laser chip 1 is first provided. The semiconductor laser chip 1 is, for example, an edge-emitting or a surface-emitting semiconductor laser chip. The semiconductor laser chip comprises a laser facet 1a, through which the laser radiation generated in the semiconductor laser chip 1 leaves the semiconductor laser chip during operation.

A reflective layer 12 is formed at the laser facet 1a. The reflective layer 12 forms part of the resonator of the semiconductor laser chip 1. The reflective layer 12 comprises, for example, metal oxides and/or semiconductor oxides, in particular alternating layers with different refractive indices.

For example, the outermost layer of the reflective layer can be formed with a material such as silicon dioxide.

An optical element 2 is also provided. The optical element 2 can be provided for beam shaping of the laser radiation, which can take place, for example, by refraction and/or diffraction. In the exemplary embodiment of FIG. 1A, the optical element 2 is formed, for example, with a glass.

The optical element 2 is arranged as close as possible to the laser facet 1a, so that a distance d between the laser facet and the optical element 2 is at most 10 μm, in particular at most 7 μm.

A laser 5 is also provided, which generates laser radiation 7. The laser radiation 7 is focused on the interface between the optical element 2 and the semiconductor laser chip 1 via an optical system 6, for example, so that a welded joint 3 is formed in the first connection area 41 after the molten material has solidified.

The schematic view of FIG. 1B shows a top view through the optical element onto the first connection area 41 between the optical element 2 and the semiconductor laser chip 1. As can be seen from FIG. 1B, the welded joint 3 is formed along a welding seam 31 which runs as a meandering curve in order to create a particularly large connection area 41 in terms of surface area. In the exemplary embodiment of FIGS. 1A and 1B, the welding seam 31 runs above the active zone 11, which is arranged at the lower end of the laser facet 1a.

This results in a laser component with the semiconductor laser chip 1 with a laser facet 1a, which comprises the active zone 11. The optical element 2 is arranged downstream in the semiconductor laser chip 1 on the laser facet 1a and the semiconductor laser chip and the optical element 2 are joined by means of the welded joint 3, which is free of welding consumables.

The welded joint 3 provides direct physical contact between the semiconductor laser chip 1 and the optical element.

The welded joint 3 comprises a welding seam 31, which extends in the first connection area 41 between the optical element 2 and the semiconductor laser chip 1 and comprises material from both components. Here, the semiconductor laser chip 1 comprises the reflective layer 12 at the laser facet 1a, the material of which forms the welded joint 3 with the material of the optical element.

The laser component remains free of a hermetically sealed housing and comprises at most one housing 9, which is not hermetically sealed.

In connection with the schematic representations of FIGS. 2A and 2B, further exemplary embodiments of a method described herein and of a laser component described herein are described.

In contrast to the method and laser component of FIGS. 1A and 1B, here the active zone 11 is laterally enclosed by at least one welding seam 31. This means that the active zone 11 is laterally surrounded by at least one welding seam 31, for example in a plane of the first connection area 41.

In the exemplary embodiment shown in FIGS. 2A and 2B, the active zone 11 is enclosed by two welding seams 31, which together form the welded joint 3. The welding seams 31 run concentrically to each other. In this way, a particularly mechanically stable connection can be made between the optical element 2 and the semiconductor laser chip 1.

By enclosing the active zone 1 with the welding seams 31, the laser facet is particularly well protected against soiling in the active zone 11.

In connection with the schematic representation of FIG. 3, a third exemplary embodiment of a method described herein and of a laser component described herein is described. In this exemplary embodiment, the welded joint comprises a welding seam 31 extending in a second joint region 42 between the optical element 2 and the carrier 8 and comprising material of the optical element 2 and the carrier 8. The carrier 8 may comprise, for example, on its upper side facing the optical element 2, a layer formed with a glass or a glass ceramic.

In this exemplary embodiment, it is additionally possible that a further welded joint 3 is formed between the optical element 2 and the semiconductor laser chip 1, as described in connection with the exemplary embodiments of FIGS. 1A, 1B, 2A and 2B. Furthermore, in this exemplary embodiment, it is possible that the distance d between the optical element 2 and the semiconductor laser 12 is selected to be somewhat larger than is the case for an exemplary embodiment in which the optical element and the semiconductor laser chip 3 are directly joined by a welded joint arranged between them. This allows higher tolerances when subordinating the optical element 2 on the semiconductor laser chip 1.

Overall, the close or direct arrangement of the optical element 2 at the laser facet 1a insulates the laser facet from the ambient air, which may contain harmful molecules. This prevents the deposition of foreign substances at the laser facet and hermetic encapsulation of the laser component is no longer necessary. This allows a particularly cost-effective production of a laser component, which can be characterized by a high ageing stability.

The invention is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

1. A laser component comprising:
a semiconductor laser chip with a laser facet comprising an active zone, and
an optical element which is arranged downstream of the semiconductor laser chip at the laser facet, wherein
the semiconductor laser chip and the optical element are joined together by means of a welded joint which is free of welding consumables,
wherein the welded joint comprises a welding seam.

2. The laser component according to the preceding claim 1,
in which a distance between the optical element and the laser facet is at most 10 μm.

3. The laser component according to claim 1, in which the optical element and the semiconductor laser chip are in direct contact with each other at the laser facet.

4. The laser component according to claim 1, comprising a carrier, wherein the semiconductor laser chip and the optical element are connected to each other by means of the carrier and the welded joint is arranged between the optical element and the carrier.

5. The laser component according to the preceding claim 4, in which the welded joint comprises a welding seam which extends in a second connection area between the optical element and the carrier and comprises material of the optical element and the carrier.

6. The laser component according to claim 1, wherein the welded joint is arranged between the optical element and the semiconductor laser chip.

7. The laser component according to claim 1, in which the welding seam extends in a first connection area between the optical element and the semiconductor laser chip and comprises material of the optical element and the semiconductor laser chip.

8. The laser component according to the preceding claim 7, in which the welding seam laterally encloses the active zone.

9. The laser component according to claim 1, which is free of a hermetically sealed housing.

10. The laser component according to claim 1, in which the semiconductor laser chip at the laser facet comprises a reflective layer comprising metal oxides and/or semiconductor oxides.

11. A method of manufacturing a laser component comprising:
providing a semiconductor laser chip with a laser facet comprising an active zone,
providing an optical element,
arranging the optical element at the laser facet,
joining the semiconductor laser chip and the optical element in a connection area by a welding process, wherein the welding process is carried out without welding consumables,
wherein the joining of the semiconductor laser chip and the optical element in a connection area by a welding process comprises generating a welding seam.

12. The method according to claim 11,
wherein the welding process is carried out by means of a laser beam which is focused in the connection area.

13. The method according to claim 12,
wherein material is melted in the connection area, which forms a welded joint after solidification.

14. The method according to claim 11, wherein a laser component is generated, the laser component comprising,
a semiconductor laser chip with a laser facet comprising an active zone, and
an optical element which is arranged downstream of the semiconductor laser chip at the laser facet,
wherein the semiconductor laser chip and the optical element are joined together by means of a welded joint which is free of welding consumables, and
wherein the welded joint comprises a welding seam.
